(19) United States
(12) Patent Application Publication
(10) Pub. No.: US 2015/0060127 A1
(43) Pub. Date: Mar. 5, 2015

(54) COMBINED PRINTED WIRING BOARD AND METHOD FOR MANUFACTURING THE SAME

(71) Applicant: IBIDEN CO., LTD., Ogaki (JP)

(72) Inventors: Makoto Terui, Ogaki (JP); Takashi Kariya, Ogaki (JP); Yoshinori Shizuno, Ogaki (JP); Masatoshi Kunieda, Ogaki (JP)

(73) Assignee: IBIDEN CO., LTD., Ogaki (JP)

(21) Appl. No.: 14/473,110

(22) Filed: Aug. 29, 2014

(30) Foreign Application Priority Data
Aug. 31, 2013 (JP) 2013-180789

(51) Int. Cl. H05K 1/11; H05K 3/40; H05K 3/12; H05K 1/02

(52) U.S. Cl. CPC H05K 1/119; H05K 1/0298; H05K 1/111; H05K 1/113; H05K 3/4046; H05K 3/125
USPC 174/263; 174/261; 29/831

(57) ABSTRACT

A combined printed wiring board includes a multilayer printed wiring board, and a wiring film fixed to a surface of the multilayer printed wiring board and including a first wiring structure formed to connect multiple semiconductor elements and a second wiring structure formed to connect the multilayer printed wiring board and each of the semiconductor elements.

### CROSS-REFERENCE TO RELATED APPLICATIONS

The present application is based upon and claims the benefit of priority to Japanese Patent Application No. 2013-180789, filed Aug. 31, 2013, the entire contents of which are incorporated herein by reference.

### BACKGROUND OF THE INVENTION

1. Field of the Invention

The present invention relates to a combined printed wiring board, more specifically, to a printed wiring board with a structure made of an organic material (epoxy resin, for example), which has dense-pitch pads to make it capable of mounting a semiconductor element. The present invention also relates to a method for manufacturing such a printed wiring board.

2. Description of Background Art

In circuit boards to be used for electronic devices such as personal computers and server computers, memory elements (DRAM, for example) and logic elements (CPU, MPU and the like, for example) are mounted on separate wiring boards.

### SUMMARY OF THE INVENTION

According to one aspect of the present invention, a combined printed wiring board includes a multilayer printed wiring board, and a wiring film fixed to a surface of the multilayer printed wiring board and including a first wiring structure formed to connect multiple semiconductor elements and a second wiring structure formed to connect the multilayer printed wiring board and each of the semiconductor elements.

According to another aspect of the present invention, a method for manufacturing a combined printed wiring board includes forming a wiring film including a first wiring structure formed to connect multiple semiconductor elements and a second wiring structure formed to connect a multilayer printed wiring board and each of the semiconductor elements, and fixing the wiring film to a surface of the multilayer printed wiring board such that the wiring film and the multilayer printed wiring board are formed to have electrical connection.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1A is a cross-sectional view illustrating the structure of a combined printed wiring board according to a first embodiment;

FIG. 1B is an enlarged view showing part of the combined printed wiring board of the first embodiment to illustrate connections of semiconductor elements, a second wiring board and a first wiring board;

FIG. 2A is a partially enlarged view illustrating a method for connecting a combined printed wiring board of the first embodiment and a semiconductor element by anisotropic conductive film (ACF);

FIG. 2B is a partially enlarged view illustrating a method for connecting a combined printed wiring board of the first embodiment and a semiconductor element by a laser via-hole (LVH) drilling;

FIG. 2C is a partially enlarged view illustrating a method for connecting a combined printed wiring board of the first embodiment and a semiconductor element by flip chip (FC);

FIG. 3A is a cross-sectional view illustrating the structure of a combined printed wiring board according to a second embodiment;

FIG. 3B is an enlarged view showing part of the combined printed wiring board of the second embodiment to illustrate connections of semiconductor elements, a second wiring board and a first wiring board;

FIG. 3C is an enlarged view showing part of the combined wiring board of the second embodiment to illustrate the connection between a second wiring board and a first wiring board;

FIG. 4A is a partially enlarged view illustrating a method for connecting a second wiring board and a first wiring board using ACF according to the second embodiment;

FIG. 4B is a partially enlarged view illustrating a printing method for connecting a second wiring board and a first wiring board according to the second embodiment;

FIG. 4C is a partially enlarged view illustrating a roller-transfer method for connecting a second wiring board and a first wiring board according to the second embodiment;

FIG. 4D is a partially enlarged view illustrating an inkjet dispensing method for connecting a second wiring board and a first wiring board according to the second embodiment;

FIG. 4E is a partially enlarged view illustrating a wire bonding method for connecting a second wiring board and a first wiring board according to the second embodiment;

FIG. 5A is a cross-sectional view of a second wiring board (wiring film) of the first embodiment;

FIG. 5B is a cross-sectional view of a second wiring board (wiring film) of the second embodiment;

FIG. 6A is a view, along with other views, illustrating a step for manufacturing a second wiring board of the first and second embodiments;

FIG. 6B is a view, along with other views, illustrating a step for manufacturing a second wiring board of the first and second embodiments;

FIG. 6C is a view, along with other views, illustrating a step for manufacturing a second wiring board of the first and second embodiments;

FIG. 6D is a view, along with other views, illustrating a step for manufacturing a second wiring board of the first and second embodiments;

FIG. 6E is a view, along with other views, illustrating a step for manufacturing a second wiring board of the first and second embodiments;

FIG. 6F is a view, along with other views, illustrating a step for manufacturing a second wiring board of the first and second embodiments;

FIG. 6G is a view, along with other views, illustrating a step for manufacturing a second wiring board of the first and second embodiments;

FIG. 6H is a view, along with other views, illustrating a step for manufacturing a second wiring board of the first and second embodiments;

FIG. 6I is a view, along with other views, illustrating a step for manufacturing a second wiring board of the first and second embodiments;

FIG. 6J is a view, along with other views, illustrating a step for manufacturing a second wiring board of the first and second embodiments;

FIG. 6K is a view, along with other views, illustrating a step for manufacturing a second wiring board of the first and second embodiments;

FIG. 6L is a view, along with other views, illustrating a step for manufacturing a second wiring board in the first and second embodiments;

FIG. 7A is a view, along with other views, illustrating a step for manufacturing a first wiring board of the first and second embodiments;

FIG. 7B is a view, along with other views, illustrating a step for manufacturing a first wiring board of the first and second embodiments;

FIG. 7C is a view, along with other views, illustrating a step for manufacturing a first wiring board of the first and second embodiments;

FIG. 7D is a view, along with other views, illustrating a step for manufacturing a first wiring board of the first and second embodiments;

FIG. 7E is a view, along with other views, illustrating a step for manufacturing a first wiring board of the first and second embodiments;

FIG. 7F is a view, along with other views, illustrating a step for manufacturing a first wiring board of the first and second embodiments;

FIG. 7G is a view, along with other views, illustrating a step for manufacturing a first wiring board of the first and second embodiments;

FIG. 7H is a view, along with other views, illustrating a step for manufacturing a first wiring board of the first and second embodiments;

FIG. 8A is a view of an example to replace the step for manufacturing a first wiring board illustrated in FIG. 7A; and

FIG. 8B is a view of an example to replace the step for manufacturing a first wiring board illustrated in FIG. 7B.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

### Structure of Combined Printed Wiring Board

To facilitate understanding of a first embodiment, a brief description of a combined printed wiring board is provided first.

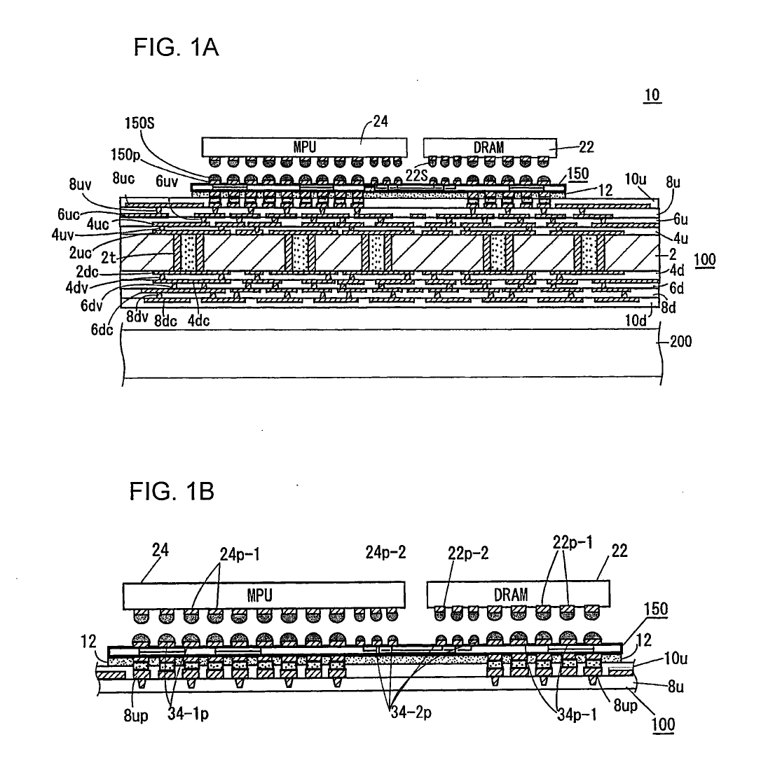

FIG. 1A is a cross-sectional view showing the structure of combined printed wiring board 10 according to the first embodiment. Combined printed wiring board 10 has first and second semiconductor elements (22, 24) mounted on one of its main surfaces, and uses the other main surface for connection with motherboard 200. The first and second semiconductor elements and a combined printed wiring board are connected by solder bumps. Connection between the combined printed wiring board and a motherboard is carried out by using solder bumps, or pin connection using stud pins formed on either side, or the like.

Combined printed wiring board 10 is formed by combining two wiring boards. First wiring board 100 is a printed wiring board made of organic material (epoxy resin, for example). In the present embodiment, a wiring board is shown where a triple-layered buildup layer is formed on each surface of a core substrate. However, such a wiring board is simply an example, and that is not the only option of the present invention. First wiring board 100 may be any printed wiring board made of organic material.

Regarding a printed wiring board such as first wiring board 100, typically, its line and space (hereinafter referred to as “L/S”) of circuit patterns is set at approximately 15 μm/15 μm, 10 μm/10 μm, or the like. Generally speaking, for reasons of manufacturing technology, the L/S of an organic printed wiring board is set at 10 μm/10 μm or greater. Accordingly, its pads are “sparse-pitch pads.”

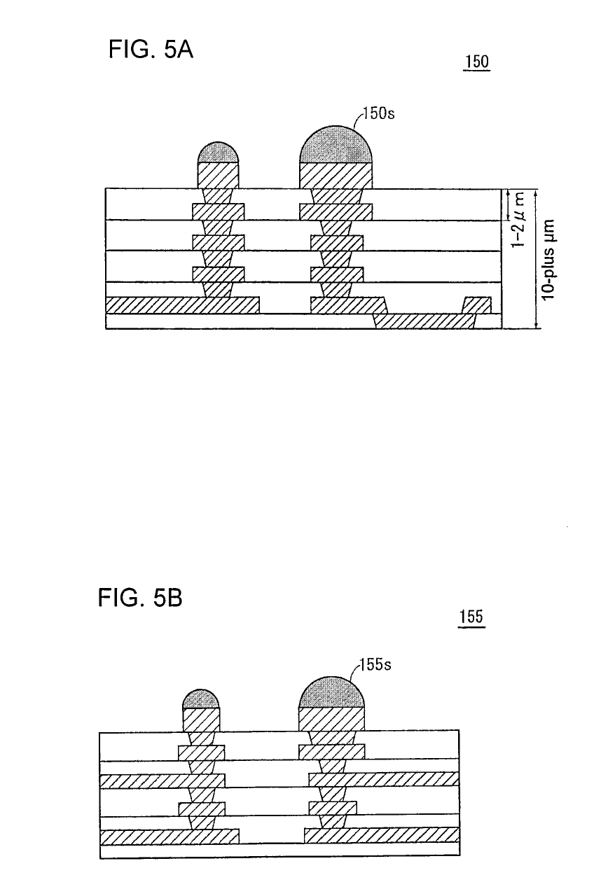

Second wiring board 150 is a wiring film (also referred to as a “wiring structure” or a “thin substrate”), which is combined with first wiring board 100 on its semiconductor-element mounting side. As described by referring to FIGS. 5A and 5B, wiring film 150 is a double-layered or multilayered wiring board formed to be a thin film, and has circuit patterns formed by a semiconductor manufacturing process. Thus, as for the L/S of its circuit patterns, typically, fine patterns such as 5 μm/5 μm, 3 μm/3 μm, 2 μm/2 μm or 1.5 μm/1.5 μm can be formed. Namely, the L/S of second wiring board 150 can be set at less than 10 μm/10 μm. Thus, its pads can be set as “dense-pitch pads.”

Wiring film 150 is formed to have both first wiring for connection between semiconductor elements to be mounted on a combined printed wiring board and second wiring for connection between the semiconductor elements and first wiring board (multilayer printed wiring board) 100.

First wiring board 100 and second wiring board 150 are manufactured separately, and are then coupled to each other to form combined printed wiring board 10.

Next, each structural component is described with reference to the accompanying drawings.

First wiring board (printed wiring board) 100 shown in FIG. 1 may be any printed wiring board made of organic material. Thus, its description is brief here. In first wiring board 100 as shown in FIG. 1, core substrate 2, through-hole conductor (2t) and conductive layers (2uc, 2dc) of the core substrate are formed. Core substrate 2 may be a multilayer wiring board manufactured using, for example, a subtractive method, semi-additive method, full-additive method or the like.

Since FIG. 1 has numerous details, its reference numerals are described here. In FIG. 1, on both surfaces of core substrate 2, reference numeral 4 is assigned for a first layer, reference numeral 6 for a second layer and reference numeral 8 for a third layer. Moreover, an affix (u) is added to the components positioned above core substrate 2, and an affix (d) is added to those positioned below core substrate 2. In addition, an affix (v) is added to via conductors and an affix (c) is added to conductive layers.

On both surfaces of core substrate 2, first interlayer resin insulation layers (4u, 4d) having first via conductors (4uv, 4dv) and second conductive layers (4uc, 4dc) are formed respectively using a buildup forming method. In addition, second interlayer resin insulation layers (6u, 6d) having second via conductors (6uv, 6dv) and second conductive layers (6uc, 6dc) are formed respectively on first interlayer resin insulation layers (4u, 4d), and third interlayer resin insulation layers (8u, 8d) having third via conductors (8uv, 8dv) and third conductive layers (8uc, 8dc) are formed respectively on second interlayer resin insulation layers (6u, 6d). Moreover, solder-resist layers or insulation resin layers (10u, 10d) are respectively formed on third interlayer resin insulation layers (8u, 8d).

First wiring board 100 may be a type that does not include plated, filled through-hole conductors, or it may be a coreless wiring board without a core substrate. The number of buildup layers is not limited to the above, and may be any other number.

The L/S of first wiring board 100 is set at 10 μm/10 μm or greater, since it is a typical printed wiring board made of organic material. Thus, its pads are “sparse-pitch pads,” for example, at a pitch of 100 μm or greater.

### Second Wiring Board

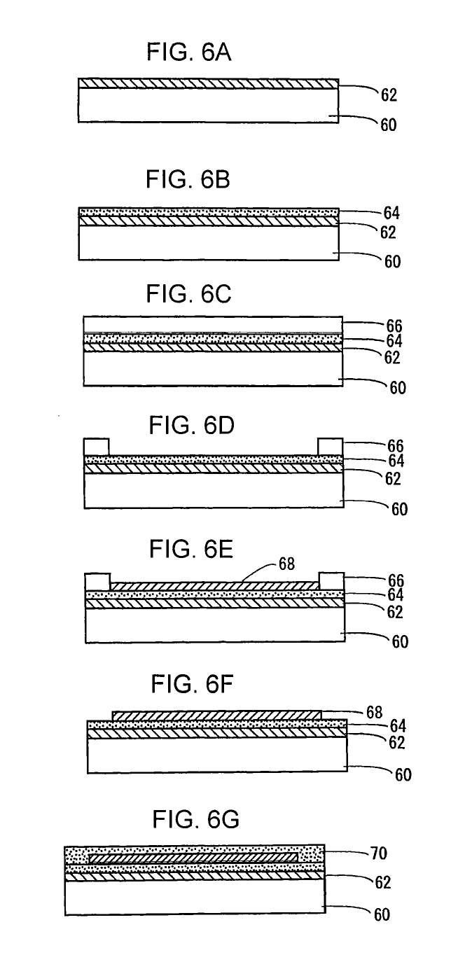

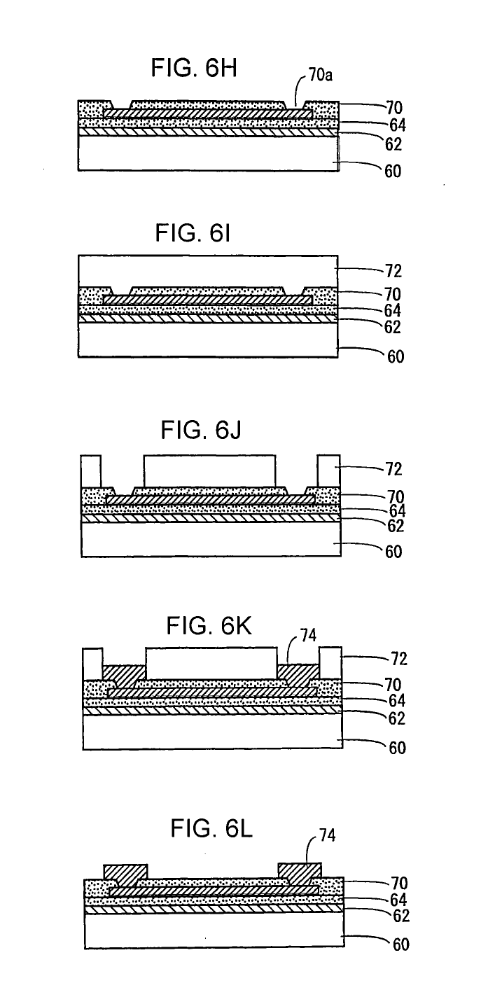

Second wiring board (wiring film) 150 is a wiring board formed to be a very thin film, which is manufactured separately from the first wiring board. As described with reference to FIG. 6A˜6K, using a semiconductor manufacturing process, second wiring board 150 is manufactured by forming double-layered or multilayered circuit patterns on a silicon or glass carrier, which is removed later. Thus, the L/S of the circuit patterns can be set at less than 10 μm/10 μm, and pads can be formed as “dense-pitch pads.” For example, the pitch is less than 100 μm. Second wiring board 150 is physically fixed to the semiconductor-element mounting surface of first wiring board 100 using bonding material 12, for example, and a predetermined electrical connection is made between the wiring boards to form combined printed wiring board 10. On the semiconductor-element mounting surface of combined printed wiring board 10, namely, on second wiring board (wiring film) 150, first semiconductor element 22 and second semiconductor element 24 are mounted side by side in close proximity.

### Semiconductor Elements

FIG. 1A shows a DRAM as first semiconductor element 22, and an MPU as second semiconductor element 24. That is not the only example, but first semiconductor element 22 is usually set to be a semiconductor memory element whereas second semiconductor element 24 is a semiconductor logic element. Thus, in an example to be described here, a DRAM is set as first semiconductor element 22 and an MPU as second semiconductor element 24. In addition, two semiconductor elements are shown in FIG. 1A, but two or more semiconductor elements may also be mounted.

Connection of Each Element

FIG. 1B is an enlarged view showing part of the structure of a combined printed wiring board according to a first embodiment illustrating a method for connecting a semiconductor element, a second wiring board (wiring film), and a first semiconductor element.

When the focus is on second wiring board (wiring film) 150, second wiring board 150 is physically fixed to first wiring board 100 on its surface facing the first wiring board. Bonding material 12 occupies the space that excludes electrical connection portions, and is made of, for example, underfill (UF), insulative film (UCF), adhesive agent or the like. Second wiring board 150 is fixed to first wiring board 100 by bonding material 12, and the space between both wiring boards is encapsulated to avoid humidity or the like.

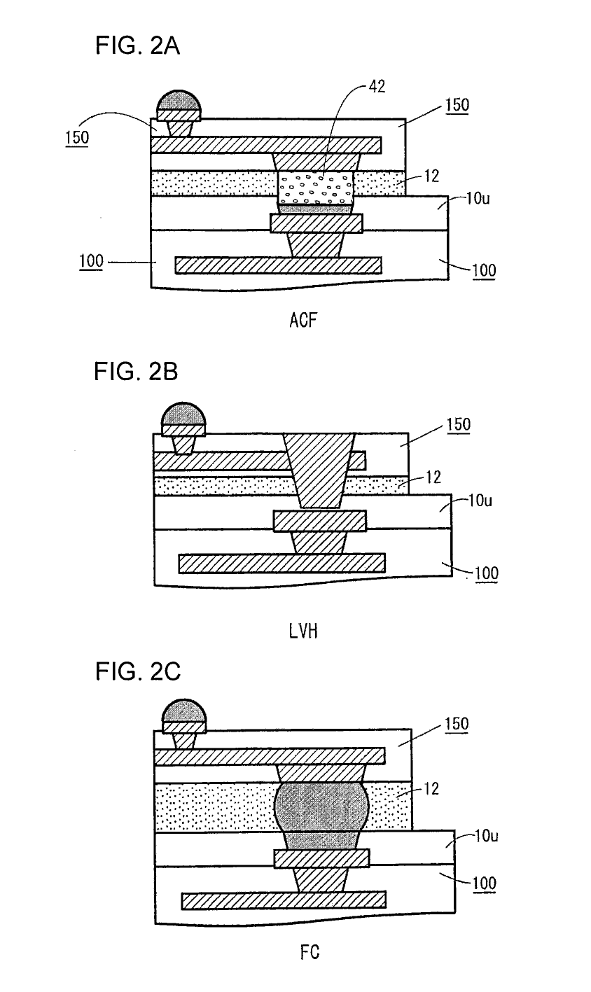

Circuit patterns of second wiring board 150 are electrically connected to circuit patterns of first wiring board 100 by a method described with reference to FIG. 2A˜2C. It is referred to as “surface mounting” because electrical connections are formed on the entire lower surface of second wiring board 150, thus differentiating it from “peripheral mounting” described later in a second embodiment.

The pitches of pads formed on both surfaces of second wiring board (wiring film) 150 are described below.

First, semiconductor elements are observed. Among the pads of DRAM 22, the pitch of pads (22p-1) for electrical connection with first wiring board 100 through second wiring board 150 is sparse, whereas the pitch of pads (22p-2) for electrical connection with MPU 24 through second wiring board 150 is dense. In the same manner, among the pads of MPU 24, the pitch of pads (24p-1) for electrical connection with first wiring board 100 through second wiring board 150 is sparse, whereas the pitch of pads (24p-2) for electrical connection with DRAM 22 through second wiring board 150 is dense.

On the semiconductor-element mounting surface of second wiring board (wiring film) 150, pads (34-1p) are sparse-pitch pads, and pads (34p-2) are dense-pitch pads to correspond to the pad pitches on semiconductor elements.

Next, when the focus is on first wiring board (printed wiring board) 100, all pads (8up) are sparse-pitch pads, and the circuit patterns are formed to be sparse. To correspond to the pad pitch of first wiring board 100, the pads of second wiring board 150 formed on the surface facing the first wiring board are sparse-pitch pads.

Regarding the pitches of pads in a semiconductor element, those shown in the drawings can be employed for a logic element, responding to a user's need. Also, a side-by-side mounting-type memory element may employ the pad pitches shown in the drawings to achieve high-speed interface with a logic element.

Among the pads of DRAM 22, pads (22p-2) for electrical connection with MPU 24 are formed to be positioned closer to MPU 24 as shown in the drawings. In the same manner, among the pads of MPU 24, pads (24p-2) for electrical connection with DRAM 22 are formed to be positioned closer to DRAM 22.

Generally, in electronic components such as personal computers and server computers, a program and data are transferred in response to a job command from a high-capacity memory device (HDD, for example) (not shown) with a relatively slow read/write capability to a semiconductor element with a relatively small capacity but with a high-speed read/write capability (memory element 22, for example), and the program is further transferred to logic element 24. To execute the program, data are sequentially called from memory element 22 to logic element 24 and computed, and the computation results are transferred from logic element 24 to be written sequentially to memory element 22. After the job is completed, the processed results are transferred to the high-capacity memory device. As described, while data are processed, data are transferred frequently in large quantities between memory element 22 and logic element 24.

Accordingly, as shown in the drawings, in an example where DRAM 22 and MPU 24 are mounted to be connected by second wiring board 150, pads of each element are formed in close proximity to each other. Such a mounting example is especially preferable since the distance from the pads of one element to the pads of another element (namely, wiring length in second wiring board 150) is reduced, and signal transmission lag is thereby further shortened. In such a mounting method, pads on the semiconductor-element mounting surface of second wiring board 150 are set as dense-pitch in the central portion and as sparse-pitch on either end, as seen in the drawings.

However, such pad formation is not limited to an example where there are severe requirements regarding transmission lag. Namely, the present embodiment is not limited to an example where regions for pads are divided into a region for sparse-pitch pads and a region for dense-pitch pads for connection of semiconductor elements (22, 24). It is an option to form multiple dense-pitch pad regions and multiple sparse-pitch pad regions and to arrange them in any desired positions. Moreover, when a second wiring board is formed by a semiconductor process, sparse-pitch pads and dense-pitch pads may coexist as long as the minimum pad pitch (minimum distance between pads) is within the limitations of manufacturing fine patterns.

Since second wiring board 150 is formed by a semiconductor manufacturing process, fine patterns are formed. Also, the same as an interposer, it also works as a pitch converter. Namely, on the semiconductor-element mounting surface of second wiring board 150, dense-pitch pads and sparse-pitch pads are both formed. The pad pitch on the surface of second wiring board 150 facing the first wiring board is sparse, due to the technological limitations of manufacturing first wiring board 100.

### Method for Electrically Connecting First Wiring Board and Second Wiring Board

FIG. 2A-2C are partially enlarged views illustrating methods for connecting a first wiring board and a second wiring board in a combined printed wiring board according to the first embodiment.

In the method shown in FIG. 2A, first wiring board (printed wiring board) 100 and second wiring board (wiring film) 150 are electrically connected by anisotropic conductive film (ACF) 42. Generally, ACF is a thermosetting resin film made by dispersing numerous fine metal-plated balls in an insulative base material. When ACF 42 is sandwiched between first wiring board 100 and second wiring board 150 and is hot-pressed, the ball portions make electrical connection in vertical directions (in a thickness direction of the wiring boards) while insulation in lateral directions (direction perpendicular to the thickness direction) is maintained.

In the method shown in FIG. 2B, a conductive pattern of first wiring board 100 and a conductive pattern of second wiring board 150 are connected by filled via conductor 44 formed by laser via-hole (LVH) drilling.

In the method shown in FIG. 2C, a conductive pattern of first wiring board 100 and a conductive pattern of second wiring board 150 are connected using flip chip technology, for example, by solder ball 46.

### Second Embodiment

### Structure of Combined Printed Wiring Board

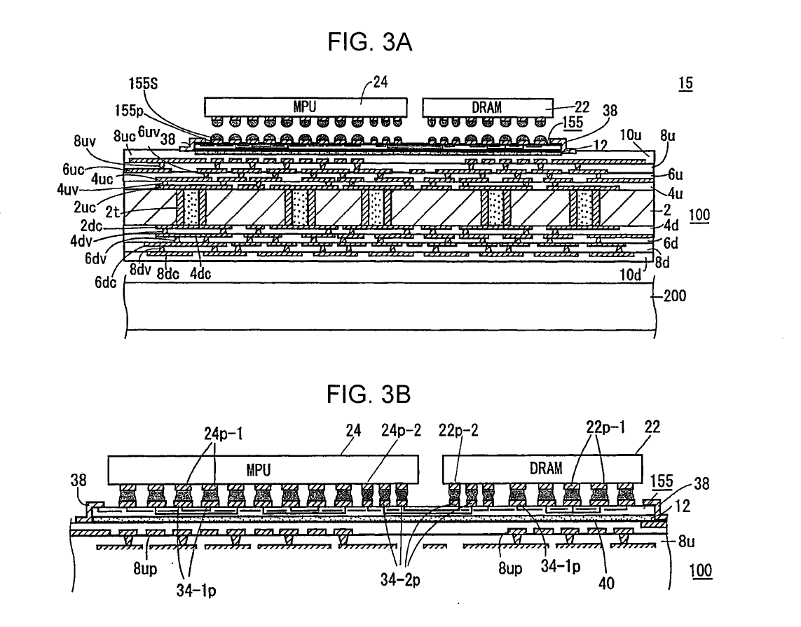

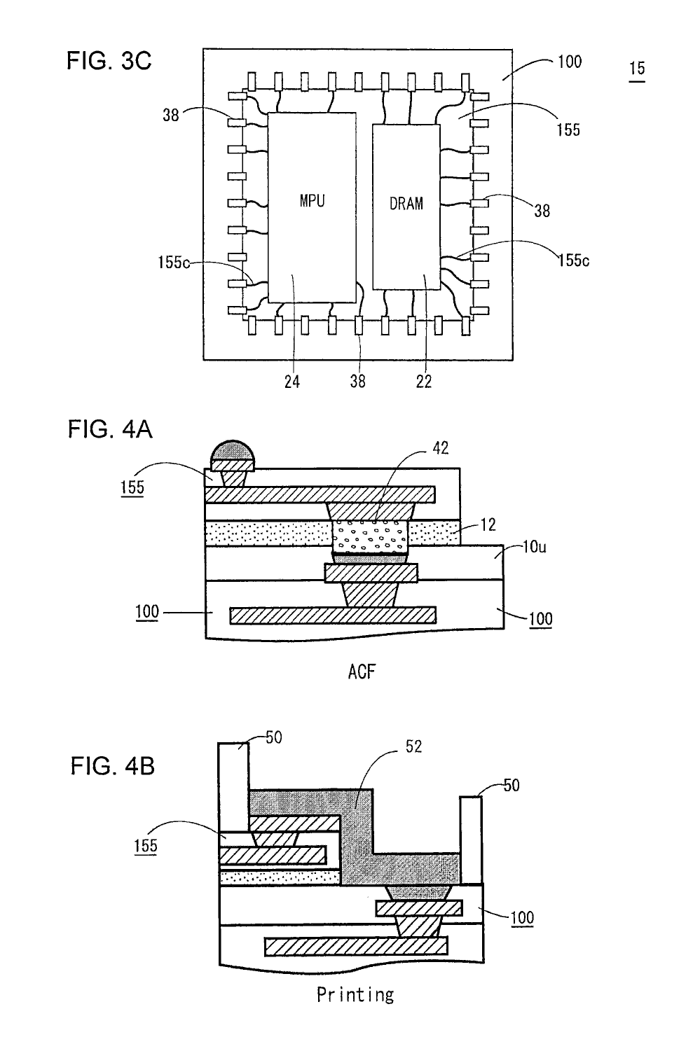

A second embodiment shown in FIGS. 3A and 3B is the same as the first embodiment except for a difference in part of a second wiring board. Thus, the second embodiment is described focusing on its difference from the first embodiment. Combined printed wiring board 15 of the second embodiment is formed by combining first wiring board (printed wiring board) 100 and second wiring board (wiring film) 155. The difference found in second wiring board 155 is the method for connecting semiconductor elements (22, 24) and first wiring board 100.

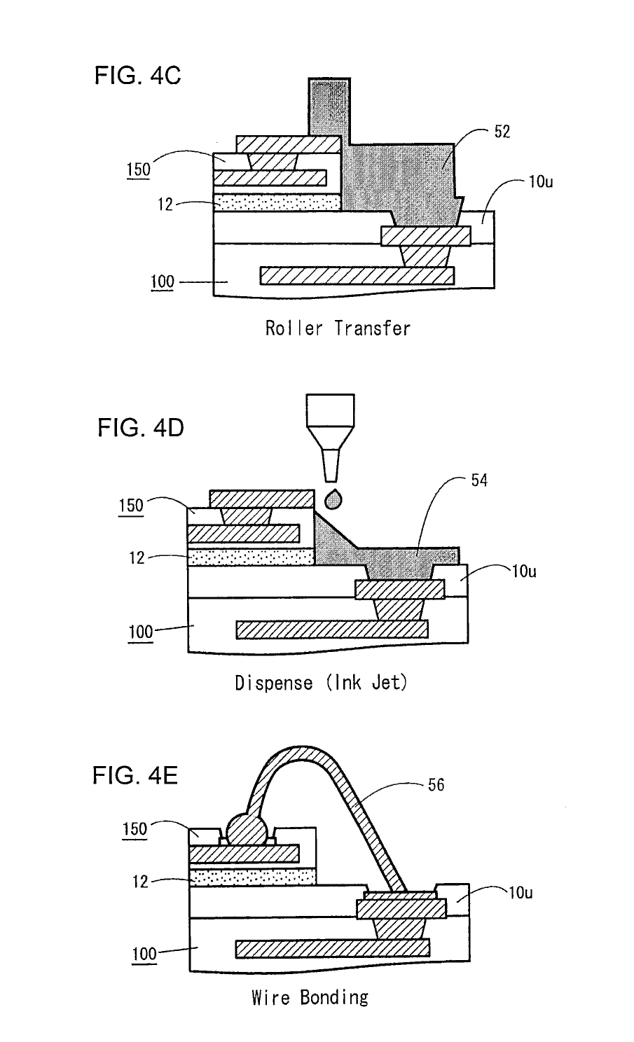

The semiconductor-element mounting surface of second wiring board 155 is substantially the same as that in the first embodiment. On the other hand, regarding the surface of second wiring board 155 facing the first wiring board, its entire surface is physically fixed to first wiring board 100 and has no electrical terminal formed thereon. Electrical connection between second wiring board 155 and first wiring board 100 is made through connection portions 38 formed on the periphery of second wiring board 155. A detailed description of connection portions 38 is provided by referring to FIG. 4A˜4E. Since electrical connection is made on the periphery of second wiring board 155, it is also referred to as “peripheral mounting,” which is differentiated from “surface mounting” described in the first embodiment.

Next, each structural component is described with reference to the drawings.

### First Wiring Board

First wiring board (printed wiring board) 100 of the second embodiment is the same as that in the first embodiment.

### Second Wiring Board

As shown in FIGS. 3A and 3B, there is no pad formed on the surface of second wiring board (wiring film) 155 facing the first wiring board. Second wiring board 155 is physically fixed to first wiring board 100. Bonding material 12 is underfill (UF), insulative film (UCF), adhesive agent or the like, which occupies the space between second wiring board 155 and first wiring board 100. Second wiring board 155 is securely fixed to first wiring board 100 by bonding material 12, and the space between both wiring boards is encapsulated to avoid humidity or the like.

As shown in FIG. 3B, electrical connection between second wiring board 155 and first wiring board 100 is made through connection portions 38 formed on the periphery of second wiring board 155.

As shown in FIG. 3C, combined printed wiring board 15 of the second embodiment is structured to have second wiring board (wiring film) 155 fixed to first wiring board (printed wiring board) 100 and to have semiconductor elements (22, 24) mounted on second wiring board 155. Circuit patterns extending from semiconductor elements (22, 24) toward first wiring board 100 are set to fan out (their pitches increasing toward the periphery) so that circuit patterns (155c) formed in second wiring board 155 pass through connection portions 38 to be connected to the circuit patterns of first wiring board 100. Regarding the semiconductor-element mounting surface, when second wiring board 155 (of the second embodiment) is compared with second wiring board 150 (of the first embodiment), a difference is that fan-out patterns are formed in the second embodiment. Here, it is not always necessary to form the fan-out patterns in the outermost layer of second wiring board 155. Part of or the entire fan-out pattern may also be formed in an inner conductive layer of second wiring board 155 with a multilayer structure, and such patterns may be electrically connected to pads formed where connection portions are formed.

### Semiconductor Elements

Semiconductor elements (22, 24) in the second embodiment are the same as those in the first embodiment.

### Method for Electrically Connecting First Wiring Board and Second Wiring Board

As described above, electrical connection of second wiring board 155 and first wiring board 100 is made through connection portions 38 formed on the periphery of second wiring board 155. FIG. 4A˜4E are partially enlarged views that illustrate specific methods of electrical connection made by connection portion 38.

In the method shown in FIG. 4A, first wiring board 100 and second wiring board 155 are physically fixed to each other by bonding material 12 and electrically connected by ACF 42. ACF 42 was described above with reference to FIG. 2A.

In the method shown in FIG. 4B, first wiring board 100 and second wiring board 155 are physically fixed to each other by bonding material 12, and are electrically connected when conductive material 52 (solder paste, for example) is printed between a circuit pattern of first wiring board 100 and a circuit pattern of second wiring board 155 with resist 50 disposed between them.

In the method shown in FIG. 4C, first wiring board 100 and second wiring board 155 are physically fixed to each other by bonding material 12, and are electrically connected by roller transfer of conductive material 52 (solder paste, for example) between a circuit pattern of first wiring board 100 and a circuit pattern of second wiring board 155.

In the method shown in FIG. 4D, first wiring board 100 and second wiring board 155 are physically fixed to each other by bonding material 12, and are electrically connected by using an inkjet printing technique, for example, by forming microscopic droplets of conductive material 54 (metal nanoparticles, for example) and by dispensing them directly on first wiring board 100.

In the method shown in FIG. 4E, first wiring board 100 and second wiring board 155 are physically fixed to each other by bonding material 12, and are electrically connected by wire bonding as a method for mounting semiconductor elements. Metal wire 56 is used to connect a circuit pattern of first wiring board 100 and a circuit pattern of second wiring board 155.

### Second Wiring Board

FIG. 5A is a cross-sectional view of second wiring board (wiring film) 150 of the first embodiment. An example of second wiring board 150 is a film-type wiring board with a thickness of each insulation layer set at 2˜4 μm and the entire thickness of all the insulation layers set at 10˜20 μm. Solder balls (150s) for connection with semiconductor elements are formed on an upper surface of the second wiring board (there are other examples of mounting without using solder balls), whereas circuit patterns for connection with the first wiring board are formed on a lower surface of the second embodiment so as to perform surface mounting.

FIG. 5B is a cross-sectional view of second wiring board (wiring film) 155 of the second embodiment. Compared with second wiring board 150, since second wiring board 155 performs peripheral mounting, no circuit pattern is formed on its lower surface for connection with the first wiring board.

### Method for Manufacturing Second Wiring Board

Methods for manufacturing second wiring boards (wiring films) (150, 155) of the first and second embodiments are described by referring to FIG. 6A′˜6L.

As shown in FIG. 6A, support sheet (also referred to as carrier) 60 is prepared. Typically, a support sheet is a flat silicon or glass sheet. Removable layer 62 is formed on its upper surface. Removable layer 62 is formed so that a second wiring board formed on the support sheet is removed from the support sheet at the final step.

As shown in FIG. 6B, insulation layer 64 is formed on removable layer 62 for second wiring board 155 of the second embodiment (see FIG. 5B). A thin insulation layer is formed by a spinning method, for example. Since peripheral mounting is employed in the second embodiment, no circuit pattern is formed on the lowermost layer.

As shown in FIG. 6C, for second wiring board 155 of the second embodiment, a seed layer is formed by sputtering or the like on insulation layer 64, and then photoresist 66 is formed. As in generally practiced semiconductor processes, liquid resist 66 is coated by spinning, for example, and then dried and cured.

As shown in FIG. 6D, photoresist 66 is patterned using an appropriate mask (not shown). Namely, resist 66 in portions to form circuit patterns is removed.

As shown in FIG. 6E, conductive layer 68 is formed in portions for forming circuit patterns. Namely, by sputtering or vacuum vapor deposition, for example, used in a semiconductor manufacturing process, a seed layer is formed on portions for forming circuit patterns on the insulation layer. Then, using the seed layer as an electrode, electrolytic copper plating is performed. Fine circuit patterns are formed by employing a semiconductor manufacturing process.

As shown in FIG. 6F, resist 66 is removed. At that time, lowermost conductive pattern 68 is formed. In second wiring board 155 of the second embodiment (see FIG. 5B), lowermost conductive pattern 68 is set on insulation layer 64. In second wiring board 150 of the first embodiment (see FIG. 5A), lowermost conductive pattern 68 is set on removable layer 62.

As shown in FIG. 6G, insulation layer 70 is further formed by a spinning method, for example, using the same process as in FIG. 6B.

As shown in FIG. 6H, via-conductor hole (70a) is formed in insulation layer 70 by photolithography, for example.

As shown in FIG. 6I, a seed layer is formed by sputtering or the like on the insulation layer where hole (70a) is formed, and then photoresist 72 is formed, using the same process as in FIG. 6C.

As shown in FIG. 6J, photoresist 72 is patterned using an appropriate mask (not shown), using the same process as in FIG. 6D.

As shown in FIG. 6K, conductive layer 74 is formed where a circuit pattern (including a via conductor) is to be formed, using the same process as in FIG. 6E.

As shown in FIG. 6E, photoresist 72 is removed, using the same process as in FIG. 6E.

To manufacture a multilayer wiring board, steps in FIG. 6G˜FIG. 6L are repeated a desired number of times. After the desired number of layers are formed, removable layer 62 is removed from support sheet 60 in the final stage. Accordingly, second wiring boards (150, 155) are respectively completed.

### Method for Manufacturing First Wiring Board (Printed Wiring Board)

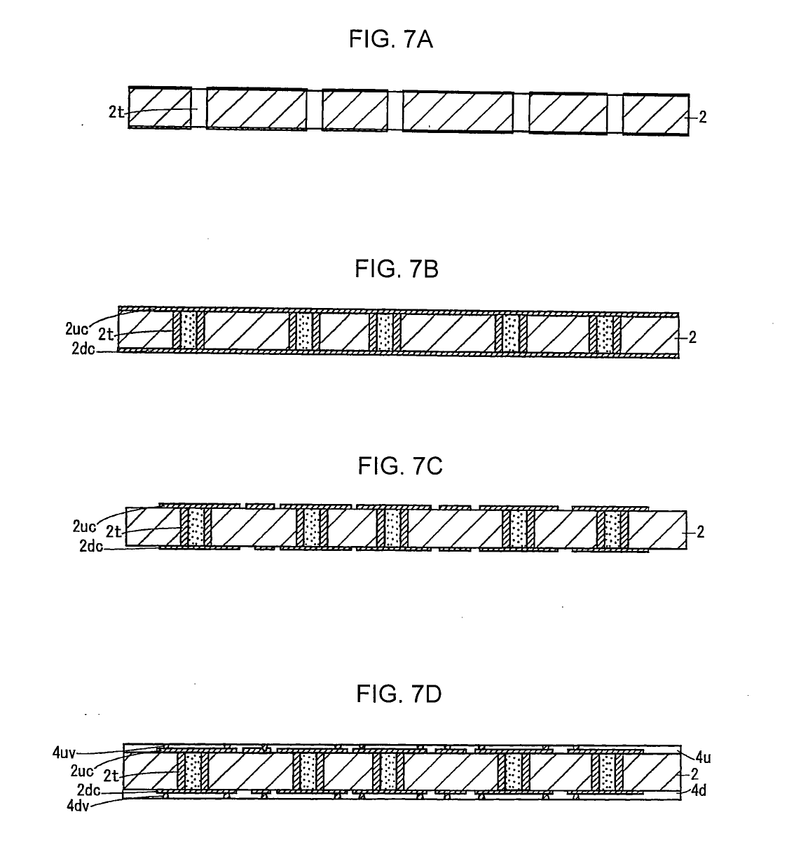

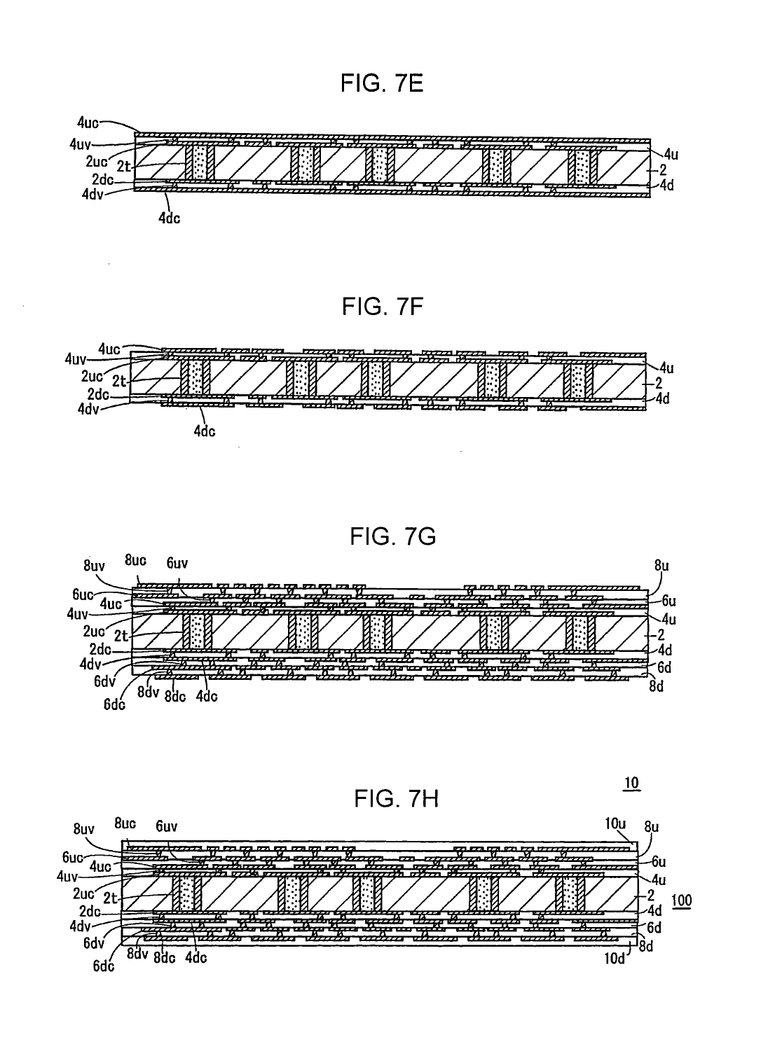

As first wiring board 100, any printed wiring board may be used. For example, first wiring board 100 may be a printed wiring board made of organic material (epoxy resin, for example). In the first embodiment shown in FIGS. 1A and 1B and in the second embodiment shown in FIGS. 3A and 3B, a wiring board is shown as an example where a triple-layered buildup layer is formed on each of both surfaces of a core substrate. Thus, a method for manufacturing such a wiring board is briefly described by referring to FIG. 7A˜7H.

As shown in FIG. 7A, a double-sided copper-clad laminate made of epoxy resin, for example, is prepared, and through holes (2t) are formed by a laser. When a semi-additive method is employed, copper foil on both surfaces is thin.

As shown in FIG. 7B, electroless copper plating is performed on the entire surface including inside the through holes, and electrolytic copper plating is then performed. Accordingly, conductive layers (2uc, 2dc) are formed respectively.

As shown in FIG. 7C, using photosensitive dry film (not shown), the conductive layers are patterned so that first conductive layers (2uc, 2dc) are respectively formed.

As shown in FIG. 7D, first interlayer insulation layers (4u, 4d) are respectively formed on both surfaces. Insulative sheet or prepreg is used and then hot pressed.

As shown in FIG. 7E, via-conductor holes are formed by laser in first interlayer insulation layers (4u, 4d) and electroless copper plating and electrolytic copper plating are performed consecutively on the entire surface including inside the holes. Accordingly, via conductors (4uv, 4dv) and conductive layers (4uc, 4dc) are respectively formed.

As shown in FIG. 7F, conductive layers are patterned using photosensitive dry film (not shown) so that second via conductors (6uv, 6dv) and second conductive layers (6uc, 6dc) are respectively formed.

As shown in FIG. 7G, the steps in FIG. 7C˜FIG. 7F are repeated twice to form second interlayer resin insulation layers (6u, 6d) where second via conductors (6uv, 6dv) and second conductive layers (6uc, 6dc) are respectively formed, and to further form third interlayer resin insulation layers (8u, 8d) where third via conductors (8uv, 8dv) and third conductive layers (8uc, 8dc) are respectively formed.

As shown in FIG. 7H, solder-resist layers or insulative resin layers (10u, 10d) are respectively formed.

### Alternative Method

In FIG. 7A, through holes (2t) are formed by a laser. Instead, through-hole conductors in an hourglass shape may be formed as follows.

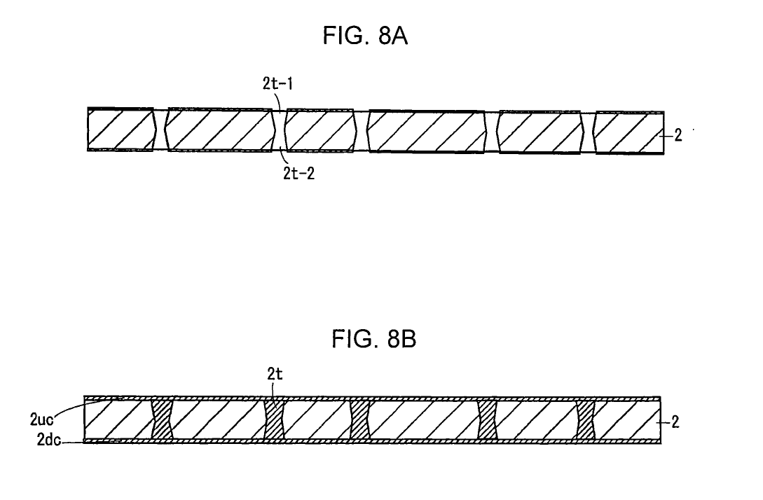

As shown in FIG. 8A, a laser is irradiated from the upper-surface side of a core substrate at a position for a through hole so that first opening (2t-1) is formed tapering with a diameter decreasing from the upper-surface side toward the lower-surface side. Then, a laser is irradiated from the lower-surface side at a position for a through hole so that second opening (2t-2) is formed tapering with a diameter decreasing from the lower-surface side toward the upper-surface side. Accordingly, an hourglass-shaped through hole made up of first opening (2t-1) and second opening (2t-2) is formed.

As shown in FIG. 8B, electroless copper plating and electrolytic copper plating are performed on the entire surface including first opening (2t-1) and second opening (2t-2). Accordingly, an hourglass-shaped hole is filled with plating and through-hole conductor and conductive layers (2uc, 2dc) are respectively formed.

The subsequent steps are the same as those described above by referring to FIG. 7C˜7H.

### Combining First Wiring Board and Second Wiring Board

In combined printed wiring board 10 according to the first embodiment, separately manufactured first wiring board 100 and second wiring board 150 are physically fixed to each other by bonding material 12, and are electrically connected by any of the methods described with reference to FIG. 2A˜2C.

In combined printed wiring board 15 according to the second embodiment, separately manufactured first wiring board 100 and second wiring board 155 are physically fixed to each other by bonding material 12, and are electrically connected by any of the methods described with reference to FIG. 4A˜4E.

As electronic devices are becoming faster, the speed of semiconductor elements increases and electrical signal transmission lag is reduced in wiring boards that electrically connect semiconductor elements to each other. Accordingly, a memory element and a logic element may be mounted in close proximity to each other (side by side) on one wiring board.

More specifically, in such a method, a separately manufactured silicon interposer may be mounted on a semiconductor-element mounting surface of a printed wiring board, and a memory element and a logic element may be arranged side by side on the other side of the silicon interposer. When an interposer is formed using a silicon substrate by a semiconductor manufacturing process, high-density circuit patterns corresponding to the patterns of semiconductor elements may be formed.

In such a silicon interposer, the pads on a surface facing semiconductor elements may be formed to have a relatively dense pitch so as to correspond to the dense-pitch pads of a semiconductor element, and the pads on the other surface facing a printed wiring board may be formed to have a relatively sparse pitch so as to correspond to sparse-pitch pads of the printed wiring board. Accordingly, the silicon interposer disposed between a printed wiring board and semiconductor elements works as a pitch converter. In the present application, typical pads in a printed wiring board are referred to as “sparse-pitch pads,” and typical pads in a semiconductor element are referred to as “dense-pitch pads.”

As described, when a silicon interposer is integrated, a printed wiring board becomes capable of responding to recent high-speed low-power consumption Wide I/O DRAMs (DRAMs where the number of data input/output terminals is widely expanded).

When a printed wiring board and a silicon interposer are combined as in the above example, the manufacturing cost becomes relatively high.

A printed wiring board according to an embodiment of the present invention is made of an organic material (such as epoxy resin) and has dense-pitch pads that make it capable of mounting semiconductor elements.

In a combined printed wiring board according to an embodiment of the present invention, wiring film is fixed to a main surface of a multilayer printed wiring board, and the wiring film is formed to have both first wiring, which is for connection between semiconductor elements to be mounted on the combined printed wiring board, and second wiring, which is for connection between each semiconductor element and the multilayer printed wiring board.

In addition, in the combined printed wiring board, dense-pitch pads and sparse-pitch pads may also be formed on the semiconductor-mounting surface of the wiring film.

Furthermore, in the combined printed wiring board, the line and space of the first wiring in the region for dense-pitch pads may be less than 10 μm/10 μm, and the line and space of the second wiring in the region for sparse-pitch pads may be 10 μm/10 μm or greater.

Yet furthermore, in the combined printed wiring board, the pitch of the dense-pitch pads may be less than 100 μm, and the pitch of the sparse-pitch pads may be 100 μm or greater.

Yet furthermore, in the combined printed wiring board, the multilayer printed wiring board and the wiring film may be fixed to each other by any of (i) underfill, (ii) insulative film and (iii) insulative adhesive.

Yet furthermore, in the combined printed wiring board, pads for mounting a semiconductor logic element and a semiconductor memory element are formed on the semiconductor-element mounting surface of the wiring film; and of those pads, pads for electrical connection between the semiconductor logic element and the semiconductor memory element may be formed in a region near each of the semiconductor elements.

Yet furthermore, in the combined printed wiring board, the pads for electrical connection between the semiconductor logic element and the semiconductor memory element may be formed to have a dense pitch, whereas the pads for electrical connection between the multilayer printed wiring board and the semiconductor logic element or the semiconductor memory element may be formed to have a sparse pitch.

Yet furthermore, in the combined printed wiring board, solder bumps may be formed on the pads formed on the semiconductor-element mounting surface of the wiring film.

Yet furthermore, in the combined printed wiring board, the multilayer printed wiring board may be (a): physically fixed to the wiring film by a resin bonding material, and then (b): electrically connected to the entire surface of the wiring film facing the multilayer printed wiring board by any of (i) anisotropic conductive film, (ii) filled via conductors, and (iii) conductive connection material.

Yet furthermore, in the combined printed wiring board, the multilayer printed wiring board may be (a): physically fixed to the wiring film on the entire surface of the wiring film facing the multilayer printed wiring board by using a resin bonding material, and then (b): electrically connected to the wiring film through connection portions formed on the periphery of the wiring film.

Yet furthermore, in the combined printed wiring board, the connection portions formed on the periphery of the wiring film may be electrically connected by any of (i) anisotropic conductive film, (ii) printing of conductive material, (iii) roller transfer of conductive material, (iv) inkjet dispensing and (v) wire bonding.

In a method for manufacturing a combined printed wiring board according to an embodiment of the present invention, a multilayer printed wiring board is manufactured by using printed wiring board manufacturing technology, a wiring film with conductive patterns is manufactured using a semiconductor manufacturing process, and the multilayer printed wiring board and the wiring film are fixed to each other. The wiring film is formed to have both first wiring for connection between semiconductor elements mounted on the combined printed wiring board, and second wiring for connection between each semiconductor element and the multilayer printed wiring board.

Furthermore, in the method for manufacturing a combined printed wiring board, dense-pitch pads and sparse-pitch pads may be formed on the semiconductor-element mounting surface of the wiring film.

Yet furthermore, in the method for manufacturing a combined printed wiring board, pads for mounting a semiconductor logic element and a semiconductor memory element may be formed on the semiconductor-element mounting surface of the wiring film, and the pads for electrically connecting the semiconductor logic element and the semiconductor memory element may be formed to be dense-pitch pads, while the pads for electrically connecting the multilayer printed wiring board and the semiconductor logic element or the semiconductor memory element are formed to be sparse-pitch pads.

A printed wiring board with a structure made of organic material according to an embodiment of the present invention has dense-pitch pads to make it capable of mounting semiconductor elements.

Obviously, numerous modifications and variations of the present invention are possible in light of the above teachings. It is therefore to be understood that within the scope of the appended claims, the invention may be practiced otherwise than as specifically described herein.

What is claimed is:

1. A combined printed wiring board, comprising:
a multilayer printed wiring board; and
a wiring film fixed to a surface of the multilayer printed wiring board and comprising a first wiring structure configured to connect a plurality of semiconductor elements and a second wiring structure configured to connect the multilayer printed wiring board and each of the semiconductor elements.

2. A combined printed wiring board according to claim 1, wherein the first wiring structure of the wiring film includes a plurality of dense-pitch pads formed on a semiconductor element mounting surface of the wiring film and a plurality of sparse-pitch pads formed on the semiconductor element mounting surface of the wiring film.

3. A combined printed wiring board according to claim 2, wherein the plurality of dense-pitch pads of the wiring film is formed such that a line and space of the dense-pitch pads is less than 10 μm/10 μm, and the plurality of sparse-pitch pads of the wiring film is formed such that a line and space of the sparse-pitch pads is 10 μm/10 μm or greater.

4. A combined printed wiring board according to claim 1, wherein the plurality of dense-pitch pads of the wiring film is formed such that a pitch of the dense-pitch pads is less than 100 μm, and the plurality of sparse-pitch pads of the wiring film is formed such that a pitch of the sparse-pitch pads is 100 μm or greater.

5. A combined printed wiring board according to claim 1, wherein the wiring film is fixed onto the surface of the multilayer printed wiring board via one of an underfill, an insulative film and an insulative adhesive agent.

6. A combined printed wiring board according to claim 1, wherein the plurality of semiconductor elements includes a logic semiconductor element and a memory semiconductor element, the first wiring structure of the wiring film includes a plurality of mounting pads configured to mount the logic semiconductor element and the memory semiconductor element on a semiconductor element mounting surface of the wiring film, and the plurality of mounting pads includes a plurality of pads configured to facilitate electrical connection between the logic semiconductor element and the memory semiconductor element.

7. A combined printed wiring board according to claim 1, wherein the plurality of semiconductor elements includes a logic semiconductor element and a memory semiconductor element, the first wiring structure of the wiring film includes a plurality of dense-pitch pads formed on a semiconductor element mounting surface of the wiring film, the second wiring structure of the wiring film includes a plurality of sparse-pitch pads formed on the semiconductor element mounting surface of the wiring film, the plurality of dense-pitch pads is configured to facilitate electrical connection between the logic semiconductor element and the memory semiconductor element, and the plurality of sparse-pitch pads is configured to facilitate electrical connection between the multilayer printed wiring board and each of the logic semiconductor element and the memory semiconductor element.

8. A combined printed wiring board according to claim 1, further comprising:
a plurality of solder bumps formed on the wiring film,
wherein the first and second wiring structures of the wiring film include a plurality of mounting pads configured to mount the semiconductor elements on a semiconductor element mounting surface of the wiring film, and the plurality of solder bumps is formed on the plurality of mounting pads, respectively.

9. A combined printed wiring board according to claim 1, further comprising:
an anisotropic conductive film connecting the wiring film and the multilayer printed wiring board such that the wiring film and the multilayer printed wiring board are configured to have electrical connection via the anisotropic conductive film,
wherein the wiring film is fixed onto the surface of the multilayer printed wiring board via a resin bonding material.

10. A combined printed wiring board according to claim 1, further comprising:
a filled via conductor connecting the wiring film and the multilayer printed wiring board such that the wiring film and the multilayer printed wiring board are configured to have electrical connection via the filled via conductor,
wherein the wiring film is fixed onto the surface of the multilayer printed wiring board via a resin bonding material.

11. A combined printed wiring board according to claim 1, further comprising:
a conductive connection structure connecting the wiring film and the multilayer printed wiring board such that the wiring film and the multilayer printed wiring board are configured to have electrical connection via the conductive connection structure,
wherein the wiring film is fixed onto the surface of the multilayer printed wiring board via a resin bonding material.

12. A method for manufacturing a combined printed wiring board, comprising:
forming a wiring film comprising a first wiring structure configured to connect a plurality of semiconductor elements and a second wiring structure configured to connect a multilayer printed wiring board and each of the semiconductor elements; and
fixing the wiring film to a surface of the multilayer printed wiring board such that the wiring film and the multilayer printed wiring board are configured to have electrical connection.

13. A method for manufacturing a combined printed wiring board according to claim 12, wherein the forming of the wiring film includes forming a plurality of dense-pitch pads on a semiconductor element mounting surface of the wiring film such that the plurality of dense-pitch pads forms the first wiring structure of the wiring film and forming a plurality of sparse-pitch pads on the semiconductor element mounting surface of the wiring film such that the plurality of sparse-pitch pads forms the second wiring structure of the wiring film.

14. A method for manufacturing a combined printed wiring board according to claim 12, wherein the forming of the wiring film includes forming a plurality of dense-pitch pads on a semiconductor element mounting surface of the wiring film such that the plurality of dense-pitch pads forms the first wiring structure of the wiring film and forming a plurality of sparse-pitch pads on the semiconductor element mounting surface of the wiring film such that the plurality of sparse-pitch pads forms the second wiring structure of the wiring film, the plurality of semiconductor elements includes a logic semiconductor element and a memory semiconductor element, the plurality of dense-pitch pads is configured to facilitate electrical connection between the logic semiconductor element and the memory semiconductor element, and the plurality of sparse-pitch pads is configured to facilitate electrical connection between the multilayer printed wiring board and each of the logic semiconductor element and the memory semiconductor element.

15. A method for manufacturing a combined printed wiring board according to claim 12, wherein the fixing of the wiring film includes forming an anisotropic conductive film connecting the wiring film and the multilayer printed wiring board such that the wiring film and the multilayer printed wiring board are configured to have electrical connection via the anisotropic conductive film, and fixing the wiring film onto the surface of the multilayer printed wiring board via a resin bonding material.

16. A method for manufacturing a combined printed wiring board according to claim 12, wherein the fixing of the wiring film includes forming a filled via conductor connecting the wiring film and the multilayer printed wiring board such that the wiring film and the multilayer printed wiring board are configured to have electrical connection via the filled via conductor, and fixing the wiring film onto the surface of the multilayer printed wiring board via a resin bonding material.

17. A method for manufacturing a combined printed wiring board according to claim 12, wherein the fixing of the wiring film includes forming a conductive connection structure connecting the wiring film and the multilayer printed wiring board such that the wiring film and the multilayer printed wiring board are configured to have electrical connection via the conductive connection structure, and fixing the wiring film onto the surface of the multilayer printed wiring board via a resin bonding material.

18. A method for manufacturing a combined printed wiring board according to claim 17, wherein the forming of the conductive connection structure includes one of printing a conductive material on a peripheral portion of the wiring film, roller-transferring a conductive material on a peripheral portion of the wiring film and dispensing a conductive material on a peripheral portion of the wiring film by an ink-jet process.

19. A method for manufacturing a combined printed wiring board according to claim 17, wherein the forming of the conductive connection structure includes forming a wire bonding on a peripheral portion of the wiring film.

20. A method for manufacturing a combined printed wiring board according to claim 12, wherein the forming of the wiring film includes forming a plurality of conductive patterns in the wiring film by a semiconductor manufacturing process such that the plurality of conductive patterns forms the first wiring structure and second wiring structure of the wiring film.
